(19) United States
(12) Patent Application Publication
(10) Pub. No.: US 2008/0283972 A1
(43) Pub. Date: Nov. 20, 2008

(54) Silicon Compounds for Producing Sio2-Containing Insulating Layers on Chips

(75) Inventors: Ekkehard Muh, Rheinfelden (DE); Hartwig Rauleder, Rheinfelden (DE); Harald Klein, Glattbach (DE); Jaroslaw Monkiewicz, Rheinfelden (DE); Iordanis Savvopoulos, Bad Soden am Taunus (DE)

Correspondence Address: OBLON, SPIVAK, MCCLELLAND MAIER & NEUSTADT, P.C., 1940 DUKE STREET, ALEXANDRIA, VA, 22314, US

(73) Assignee: DEGUSSA AG, Duesseldorf (DE)

(21) Appl. No.: 10/586,675

(22) PCT Filed: Dec. 22, 2004
(86) PCT No.: PCT/EP2004/053669

§ 371 Date: Aug. 4, 2008

(30) Foreign Application Priority Data
Feb. 19, 2004 (DE) 10 2004 008 442.4

(51) Int. Cl. H01L 23/58; H01L 21/31

(52) U.S. Cl. 257/632; 438/787; 257/E21.24; 257/E23.001

(57) ABSTRACT

The present invention relates to a process for producing an SiO₂-containing insulating layer on chips and the use of specific precursors for this purpose. The invention further relates to an insulating layer obtainable in this way and also to chips which have been provided with such an insulating layer.

The present invention relates to a process for producing an SiO₂-containing insulating layer on chips and the use of specific precursors for this purpose. The invention further relates to an insulating layer obtainable in this way and also to chips which have been provided with such an insulating layer.

Efforts are continually being made to provide computer chips having an ever better performance, which can be achieved, for example, by increasing the transistor density and continuing miniaturization. At the same time, chips based on high-purity silicon are subject to strong cost pressures. This means, firstly, that sometimes novel insulation layers having modified properties become a success and, secondly, these also have to be produced inexpensively. The insulating effect is based on a reduction in the electrostatic force between two charges separated by this substance. In this way, the capacitative interaction between adjacent interconnects is reduced.

In present-day chip production, insulation layers are predominantly made up of siliceous layers based on SiO₂, using tetraethoxysilane (TEOS) in particular from the comprehensive range of silanes as precursor for producing the layers. TEOS has given good results with regard to workability. The insulating action achievable with this material has hitherto been sufficient. The mechanical properties of the layers produced using TEOS are generally good. They are produced by the CVD (Chemical Vapor Deposition) technique or the spin-on method (Andreas Weber, “Chemical vapordeposition-eine Übersicht”, Spektrum der Wissenschaft, April 1996, pages 86 to 90; Michael McCoy, “Completing the circuit” C&EN, November 2000, pages 17 to 24).

It is an object of the present invention to provide a further precursor for producing an insulating layer on chips.

According to the invention, this object is achieved as set forth in the claims.

Thus, it has surprisingly been found that a specific silicon compound from the group consisting of vinylalkoxysilanes, alkylalkoxysilanes, alkylarylalkoxysilanes, arylalkoxysilanes, methyl orthosilicate and C₃-C₅-alkyl orthosilicates, orthosilicates of glycols, orthosilicates of polyethers, hydrogenalkoxysilanes, hydrogenaryloxysilanes, alkylhydrogensilanes, alkylhydrogenalkoxysilanes, dialkylhydrogenalkoxysilanes, arylhydrogensilanes, arylhydrogenalkoxysilanes, acetoxysilanes, silazanes, siloxanes, organofunctional silanes bearing at least one acetoxy, azido, amino, cyano, cyanato, isocyanato or ketoximato group, organofunctional silanes containing at least one heterocycle, with the silicon atom being able to belong to the heterocycle itself or be covalently bound to this, and mixtures of at least two silicon compounds of the classes mentioned here and mixtures of tetraethoxysilane with at least one silicon compound of the classes mentioned here can advantageously be used in a simple, economical and effective manner as precursor for producing an insulating layer on chips. As alkoxy groups, preference is given, in particular, to methoxy and ethoxy groups. Thus, silicon compounds mentioned here can be used according to the invention as precursors in the production of SiO₂-containing insulating layers on chips, advantageously by means of the CVD technique or by the spin-on method. Insulating layers on chips which are obtainable according to the invention advantageously have excellent performance and advantageous costs.

The present invention accordingly provides a process for producing an SiO₂-containing insulating layer on chips, wherein at least one silicon compound from the group consisting of vinylsilanes, alkylalkoxysilanes, alkylarylalkoxysilanes, arylalkoxysilanes, C₁- and C₃-C₅-alkyl orthosilicates, orthosilicates having glycol radicals, orthosilicates having polyether radicals, hydrogenalkoxysilanes, hydrogenaryloxysilanes, alkylhydrogensilanes, alkylhydrogenalkoxysilanes, dialkylhydrogenalkoxysilanes, arylhydrogensilanes, arylhydrogenalkoxysilanes, acetoxysilanes, silazanes, siloxanes, organofunctional silanes bearing at least one acetoxy, azido, amino, cyano, cyanato, isocyanato or ketoximato group, organofunctional silanes containing at least one heterocycle, with the silicon atom being able to belong to the heterocycle itself or be covalently bound to this, and mixtures of at least two of the abovementioned compounds and mixtures of tetraethoxysilane with at least one of the abovementioned silicon compounds is used as precursor.

Particularly preferred but nonexhaustive examples of precursors which can be used according to the invention are the following compounds:

Vinylalkoxysilanes such as vinyltrimethoxysilane, vinyltriethoxysilane, vinylsilanes having polyether radicals or glycol radicals and corresponding essentially to the formula

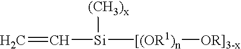

where R¹=—(CH₂)—, —(CH₂)₂—, —(CH₂)₃, —(CH₂)₄—, —(CH₂)₅—, —(CH₂)₆—, x=O or 1, n=1 to 40, preferably from 1 to 15, in particular from 1 to 10, and R═H, —CH₃, —C₂H₅, —C₃H₇, —C₄H_{g}, —C₅H₁₁, —C₈H₁₃, where groups R can also be branched alkyl radicals, for example vinyltris(methoxyethoxy)silane, and also vinylalkylalkoxysilanes such as vinylmethyldialkoxysilane, and also vinylarylalkoxysilanes, methyltrimethoxysilane, ethyltrimethoxysilane, ethyltriethoxysilane, i- and n-propyltrimethoxysilane, i- and n-propyltriethoxysilane, i- and n-butyltrimethoxysilane, i- and n-butyltriethoxysilane, tert-butyltrimethoxysilane, tert-butyltriethoxysilane, phenyltrimethoxysilane, phenyltriethoxysilane, n-propylmethyldimethoxysilane, methyl orthosilicate, n-propyl orthosilicate, tetrabutyl glycol orthosilicate, amyltrimethoxysilane, bis(methyltriethylene glycol)dimethylsilane, 2-(cyclohex-3-enyl)ethyltriethoxysilane, cyclohexylmethyldimethoxysilane, cyclohexyltrimethoxysilane, cyclopentylmethyldimethoxysilane, cyclopentyltrimethoxysilane, di-i-butyldimethoxysilane, di-i-propyldimethoxysilane, dicyclopentyldimethoxysilane, dimethyldiethoxysilane, diphenyldimethoxysilane, vinyltriacetoxysilane, 2-phenylethyltriethoxysilane, 2-phenylethylmethyldiethoxysilane, 3-methacryloxypropyltrimethoxysilane, 3-acryloxypropyltrimethoxysilane, 3-methacryloxy-2-methylpropyltrimethoxysilane, 3-acryloxy-2-methylpropyltrimethoxysilane, methyldiethoxysilane, methylpropyldiethoxysilane, methylpropyldimethoxysilane, trimethoxysilane, triethoxysilane, dimethylethoxysilane, triethylsilane, methyltriacetoxysilane, ethyltriacetoxysilane, vinyltriacetoxysilane, di-tert-butoxydiacetoxysilane, heptamethyldisilazane, hexamethyldisilazane, N,O-bis(trimethylsilyl)acetamide, 1,3-divinyltetramethyldisilazan, hexamethyldisiloxane, 1,3-divinyltetramethyldisiloxane, 1,1,3,3-tetramethyldisiloxane, 3-acetoxypropyltrimethoxysilane, 3-acetoxypropyltriethoxysilane, trimethylsilylacetate, 3-azidopropyltriethoxysilane, N-(n-butyl)-3-aminopropyltrimethoxysilane, 3-aminopropyltrimethoxysilane, 3-aminopropyltriethoxysilane, 3-amino-2-methylpropyltriethoxysilane, 3-aminopropylmethyldimethoxysilane, 3-aminopropylmethyldiethoxysilane, 3-cyanopropyltriethoxysilane, trimethylsilyl nitrite, 3-cyanatopropyltrimethoxysilane, 3-cyanatopropyltriethoxysilane, 3 isocyanatopropyltrimethoxysilane, isocyanatopropyltriethoxysilane, methyltris(methylethylketoximato)silane, N-(1-triethoxysilyl)-ethylpyrrolidone-2,3-(4,5-dihydroimidazolyl)propyltriethoxysilane, 1-trimethylsilyl-1,2,4-triazole, 3-morpholinopropylmethyldiethoxysilane, 3-morpholinopropyltriethoxysilane and 2,2-dimethoxy-1-oxa-2-sila-6,7-benzocycloheptane and also condensed or cocondensed silanes, oligosiloxanes and polysiloxanes derived from, for example, one or more of the abovementioned precursors, e.g. vinyltrimethoxysilane oligomers (DYNASYLAN® 6490), vinyltriethoxysilane oligomers (DYNASYLAN® 6498) and vinyl/alkylsiloxane cooligomers (DYNASYLAN® 6590), to name only a few examples, or cocondensed oligosiloxanes a may be found, by way of example but not exclusively, in EP 0 716 127 A2 and EP 0 716 128 A2 (including DYNASYLAN® HS 2627, DYNASYLAN® HS 2909, DYNASYLAN® HS 2776, DYNASYLAN® HS 2775, DYNASYLAN® HS 2926).

In the process of the invention, the production of an SiO₂-containing insulating layer on chips is preferably carried out in a manner known per se by means of the CVD technique or by the spin-on method.

In general, the process of the invention for producing an SiO₂-containing insulating layer by means of the CVD technique is carried out as follows:

In a suitable reactor, e.g. Applied Centura HAT or Novellus Concept One 200, the abovementioned precursors based on silicon or mixtures of precursors can be vaporized and allowed to react on hot surfaces, e.g. a silicon wafer, to form solid layer material. Relatively recent modifications of this process, for example RPCVD (reduced pressure chemical vapor deposition), LPCVD (low pressure chemical vapor deposition) and PECVD (plasma enhanced chemical vapor deposition), have been found to be advantageous, since they make it possible for more rapid deposition to be achieved at a sometimes significantly reduced temperature.

Furthermore, the production according to the invention of an SiO₂-containing insulating layer on chips can be carried out by the spin-on method, in which the procedure is generally as follows:

Liquid, silicon-containing compounds, mixtures of liquid, silicon-containing compounds or solutions of these compounds in suitable vaporizable solvents are usually applied to the surface of a silicon wafer and a uniform thin film is produced by rotation of the wafer. The film produced in this way can be cured by subsequent drying at from 20 to 500° C.

The present invention further provides an insulating layer for chips which is obtainable by the process of the invention.

The invention likewise provides a chip having an insulating layer obtainable by the process of the invention.

Furthermore, the present invention provides for the use according to the invention of precursors disclosed here for producing an insulating layer on chips.

1. A process for producing an SiO₂-containing insulating layer on chips, wherein at least one silicon compound from the group consisting of vinylsilanes, alkylalkoxysilanes, alkylarylalkoxysilanes, arylalkoxysilanes, C₁- and C₃-C₅ alkyl orthosilicates, orthosilicates having glycol radicals, orthosilicates having polyether radicals, hydrogenalkoxysilanes, hydrogenaryloxysilanes, alkyl-hydrogensilanes, alkylhydrogenalkoxysilanes, dialkylhydrogenalkoxysilanes, arylhydrogensilanes, arylhydrogenalkoxysilanes, acetoxysilanes, silazanes, siloxanes, organofunctional silanes bearing at least one acetoxy, azido, amino, cyano, cyanato, isocyanato or ketoximato group, organofunctional silanes containing at least one heterocycle, with the silicon atom being able to belong to the heterocycle itself or be covalently bound to this, and mixtures of at least two silicon compounds of the classes mentioned here and mixtures of tetraethoxysilane with at least one silicon compound of the classes mentioned here is used as precursor.

2. The process as claimed in claim 1, wherein the production of an SiO₂-containing insulating layer on chips is carried out by means of the CVD technique or by the spin-on method.

3. The process as claimed in claim 1, wherein at least one precursor from the group consisting of vinyltrimethoxysilane, vinyltriethoxysilane, vinylsilanes having polyether radicals or glycol radicals, vinyltris(methoxyethoxy)silane, vinylmethyldialkoxysilane, vinylarylalkoxysilanes, methyltrimethoxysilane, ethyltrimethoxysilane, ethyltriethoxysilane, propyltrimethoxysilane, propyltriethoxysilane, butyltrimethoxysilanes, butyltriethoxysilanes, phenyltrimethoxysilane, phenyltriethoxysilane, propylmethyldimethoxysilane, methyl orthosilicate, n-propyl orthosilicate, tetrabutyl glycol orthosilicate, amyltrimethoxysilane, bis(methyltriethyleneglycol)dimethylsilane, 2-(cyclohex 3-enyl)ethyltriethoxysilane, cyclohexylmethyldimethoxysilane, cyclohexylmethyltrimethoxysilane, cyclopentylmethyldimethoxysilane, cyclopentyltrimethoxysilane, di-i-butyldimethoxysilane, di-i-propyldimethoxysilane, dicyclopentyldimethoxysilane, dimethyldiethoxysilane, diphenyldimethoxysilane, vinyltriacetoxysilane, 2-phenylethyltriethoxysilane, 2-phenylethylmethyldiethoxysilane, 3-methacryloxypropyltrimethoxysilane, 3-acryloxypropyltrimethoxysilane, 3-methacryloxy-2-methyl-propyltrimethoxysilane, 3-acryloxy-2-methylpropyldimethoxysilane, methyldiethoxysilane, methylpropyldiethoxysilane, methylpropyldimethoxysilane, trimethoxysilane, triethoxysilane, dimethylethoxysilane, triethylsilane, methyltriacetoxysilane, ethyltriacetoxysilane, vinyltriacetoxysilane, di-tert-butoxydiacetoxysilane, heptamethyldisilazane, hexamethyldisilazane, N,O-bis(trimethylsilyl)acetamide, 1,3-divinyltetramethyldisilazane, hexamethyldisiloxane, 1,3-divinyltetramethyldisiloxane, 1,1,3,3-tetramethyldisiloxane, 3-acetoxypropyltrimethoxysilane, 3-acetoxypropyltriethoxysilane, trimethylsilyl acetate, 3-azido-propyltriethoxysilane, N-(n-butyl)-3-aminopropyltrimethoxysilane, 3-amino-propyltrimethoxysilane, 3-aminopropyltriethoxysilane, 3-amino-2-methylpropyltriethoxysilane, 3-aminopropylmethyldimethoxysilane, 3-aminopropylmethyldiethoxysilane, 3-cyanopropyltriethoxysilane, trimethylsilyl nitrile, 3-cyanatopropyltrimethoxysilane, 3-cyanatopropyltriethoxysilane, 3-isocyanatopropyltrimethoxysilane, isocyanatopropyltriethoxysilane, methyltris(methylethylketoximato)silane, N-(1-triethoxysilyl)ethylpyrrolidone-2,3-(4,5-dihydroimidazolyl)propyltriethoxysilane, 1-trimethylsilyl-1,2,4-triazole, 3-morpholinopropylmethyldiethoxysilane, 3-morpholinopropyltriethoxysilane and 2,2-dimethoxy-1-oxa-2-sila-6,7-benzocycloheptane and condensed or cocondensed silanes, oligosiloxanes and polysiloxanes is used.

4. An insulating layer for chips obtainable as claimed in claim 1.

5. A chip having an insulating layer obtainable as claimed in claim 1.

6. The method of using precursors as set forth in claim 1 for producing an insulating layer on chips.
